(19) United States
(12) Patent Application Publication
(10) Pub. No.: US 2025/0218738 A1
(43) Pub. Date: Jul. 3, 2025

(54) SUBSTRATE PROCESSING APPARATUS, ELECTRODE ASSEMBLY, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Tsuyoshi TAKEDA, Toyama-shi (JP)

(73) Assignee: Kokusai Electric Corporation, Tokyo (JP)

(21) Appl. No.: 19/086,287

(22) Filed: Mar. 21, 2025

Related U.S. Application Data
(63) Continuation of application No. PCT/JP2023/036232, filed on Oct. 4, 2023.

(30) Foreign Application Priority Data
Dec. 22, 2022 (JP) 2022-206095

(51) Int. Cl. H01J 37/32

(52) U.S. Cl. CPC H01J 37/32541; H01J 37/32568; H01J 2237/2001

(57) ABSTRACT

There is provided a technique that includes: a process chamber in which a substrate is processed; a plurality of primary electrodes connected to a high frequency power supply provided outside the process chamber, wherein each of the plurality of primary electrodes is configured to be folded back at an upper portion thereof; and a secondary electrode to which a reference potential is applied.

### CROSS-REFERENCE TO RELATED PATENT APPLICATION

This application is a bypass continuation application of PCT International Application No. PCT/JP2023/036232, filed on Oct. 4, 2023, in the WIPO, the international application being based upon and claiming the benefit of priority from Japanese Patent Application No. 2022-206095, filed on Dec. 22, 2022, in the Japanese Patent Office, the entire contents of which are hereby incorporated by reference.

### BACKGROUND

### 1. Field

The present disclosure relates to a substrate processing apparatus, an electrode assembly, a substrate processing method, a method of manufacturing a semiconductor device and a non-transitory computer-readable recording medium.

### 2. Related Art

As a part of a manufacturing process of a semiconductor device, a substrate processing may be performed. According to the substrate processing, various films such as an insulating film, a semiconductor film and a conductor film may be formed on a substrate by loading (transferring) the substrate into a process chamber of a substrate processing apparatus and supplying a source gas and a reactive gas into the process chamber, or may be removed from the substrate.

In a mass-produced device in which a fine pattern is formed, the substrate processing may be performed at a lower temperature such that a diffusion of impurities can be suppressed or such that a low heat resistance material such as an organic material can be used.

In order to address such a problem described above, the substrate processing by using a plasma is generally performed. However, in such a substrate processing, it may be difficult to uniformly process the films described above.

### SUMMARY

According to the present disclosure, there is provided a technique capable of performing a substrate processing more uniformly.

According to an embodiment of the present disclosure, there is provided a technique that includes: a process chamber in which a substrate is processed; a plurality of primary electrodes connected to a high frequency power supply provided outside the process chamber, wherein each of the plurality of primary electrodes is configured to be folded back at an upper portion thereof; and a secondary electrode to which a reference potential is applied.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a horizontal cross-section taken along a line A-A of the substrate processing apparatus shown in FIG. 1.

FIG. 3A is a diagram schematically illustrating a perspective view when a plurality of electrodes according to the embodiments of the present disclosure are installed in a quartz cover, FIG. 3B is a diagram schematically illustrating a positional relationship among a heater, the quartz cover, the electrodes, a plurality of protrusions for fixing the electrodes and a reaction tube according to the embodiments of the present disclosure, FIG. 3C is a diagram schematically illustrating the positional relationship among the heater, the quartz cover, the electrodes, the protrusions for fixing the electrodes and the reaction tube in the cross-section taken along the line A-A of FIG. 3A, FIG. 3D is a diagram schematically illustrating an exemplary configuration in which a primary electrode according to the embodiments of the present disclosure is formed as a single body in a flat plate shape, and FIG. 3E is a diagram schematically illustrating an exemplary configuration in which the primary electrode according to the embodiments of the present disclosure is formed as a separably assembled structure configured by connecting two flat plate structures (vertical structures) with an upper structure (connecting structure).

FIG. 4A is a diagram schematically illustrating a front view of an electrode among the electrodes according to the embodiments of the present disclosure, and FIG. 4B is a diagram schematically illustrating a state in which the electrode is fixed to the quartz cover.

FIG. 5 is a block diagram schematically illustrating an exemplary configuration of a controller and related components of the substrate processing apparatus shown in FIG. 1.

FIG. 6 is a flow chart schematically illustrating an example of a substrate processing performed by using the substrate processing apparatus shown in FIG. 1.

### DETAILED DESCRIPTION

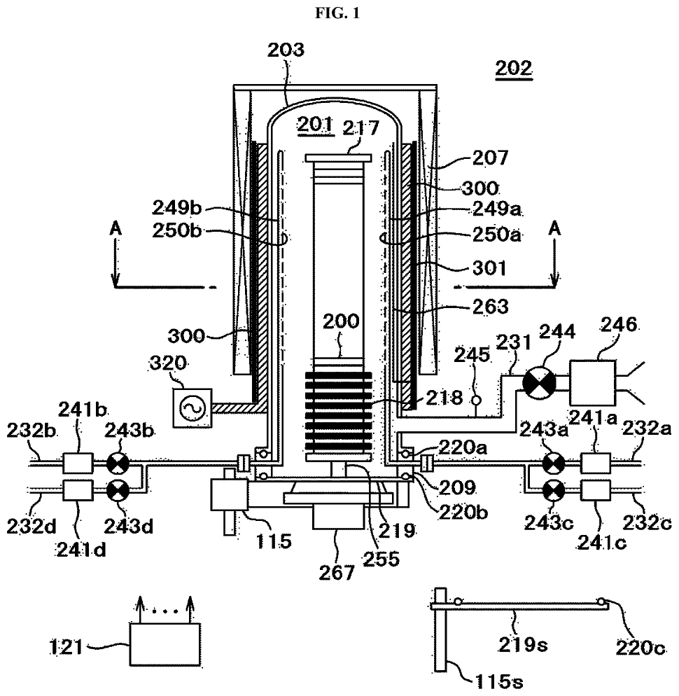

Hereinafter, one or more embodiments (also simply referred to as “embodiments”) of the technique of the present disclosure will be described in detail mainly with reference to FIGS. 1 to 4. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus (Heating Apparatus)

As shown in FIG. 1, a substrate processing apparatus according to the present embodiments includes a process furnace 202 such as a vertical type furnace. The process furnace 202 includes a heater 207 serving as a heating apparatus (which is a heating structure or a heating system) configured to heat a substrate (wafer) 200. The heater 207 is of a cylindrical shape, and is vertically installed while being supported by a heater base (not shown) serving as a support plate. In addition, the heater 207 is provided outside an electrode fixture 301 serving as an electrode fixing jig, which will be described later. As described later, the heater 207 also functions as an activator (also referred to as an “exciter”) capable of activating (or exciting) a gas by a heat.

### <Process Chamber>

The electrode fixture 301 serving as the electrode fixing jig described later is provided in an inner side of the heater 207, and a plurality of electrodes 300 of a plasma generator (which is a plasma generating structure) described later are provided in an inner side of the electrode fixture 301. Hereinafter, each of the electrodes 300 may also be referred to as an “electrode 300”. Further, a reaction tube 203 is provided in an inner side of the electrode 300 to be aligned in a manner concentric with the heater 207. For example, the reaction tube 203 is made of a heat resistant material such as quartz (SiO₂), silicon carbide (SiC) and silicon nitride (SiN). The reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). The manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. The reaction tube 203 is installed vertically while the manifold 209 is being supported by the heater base (not shown). A process vessel (also referred to as a “reaction vessel”) is constituted mainly by the reaction tube 203 and the manifold 209. A process chamber 201 is provided in a hollow cylindrical portion of the process vessel. The process chamber 201 is configured to accommodate a plurality of wafers including the wafer 200 serving as the substrate. In other words, the process chamber 201 in which the wafer 200 is processed is defined by the reaction tube 203. Hereinafter, the plurality of wafers including the wafer 200 may also be simply referred to as “wafers 200”. For example, the process vessel is not limited to such a configuration described above. For example, the reaction tube 203 alone may also be referred to as the “process vessel”.

### <Gas Supplier>

Nozzles 249a and 249b are provided in the process chamber 201 so as to penetrate a side wall of the manifold 209. The nozzles 249a and 249b serve as a first supply structure and a second supply structure, respectively. The nozzles 249a and 249b may also be referred to as a first nozzle and a second nozzle, respectively. For example, each of the nozzles 249a and 249b is made of a heat resistant material such as quartz and SiC. Gas supply pipes 232a and 232b are connected to the nozzles 249a and 249b, respectively. For example, as described above, the two nozzles 249a and 249b and the two gas supply pipes 232a and 232b are provided at the process vessel such that a plurality types of gases can be supplied into the process chamber 201 via the nozzles 249a and 249b and the gas supply pipes 232a and 232b. In addition, when the reaction tube 203 alone constitutes the process vessel, the nozzles 249a and 249b may be provided in the process chamber 201 so as to penetrate a side wall of the reaction tube 203.

Mass flow controllers (also simply referred to as “MFCs”) 241a and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c and 232d through which an inert gas is supplied are connected to the gas supply pipes 232a and 232b, at a downstream side of the valve 243a of the gas supply pipe 232a and a downstream side of the valve 243b of the gas supply pipe 232b, respectively. MFCs 241c and 241d and valves 243c and 243d are sequentially installed at the gas supply pipes 232c and 232d, respectively, in this order from upstream sides to downstream sides of the gas supply pipes 232c and 232d in the gas flow direction.

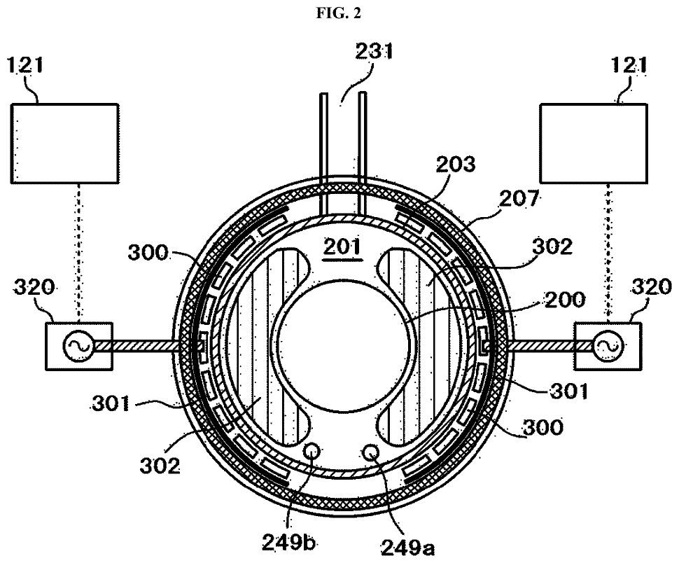

As shown in FIGS. 1 and 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a stacking direction of the wafers 200). That is, the nozzles 249a and 249b are provided beside edges (peripheries) of the wafers 200 loaded (transferred) into the process chamber 201, and are provided perpendicular to surfaces (flat surfaces) of the wafers 200. A plurality of gas supply holes 250a and a plurality of gas supply holes 250b are provided at side surfaces of the nozzles 249a and 249b, respectively. Gases can be supplied through the gas supply holes 250a and the gas supply holes 250b, respectively. The gas supply holes 250a and the gas supply holes 250b are open toward a center of the reaction tube 203, and are configured such that the gases are supplied toward the wafers 200 through the gas supply holes 250a and the gas supply holes 250b. The gas supply holes 250a and the gas supply holes 250b are provided from the lower portion toward the upper portion of the reaction tube 203.

According to the present embodiments, the gases are respectively supplied through the nozzles 249a and 249b, which are provided in a vertically elongated annular space (that is, a cylindrical space) when viewed from above defined by an inner surface of the side wall (that is, the inner wall) of the reaction tube 203 and the edges (peripheries) of the wafers 200 arranged in the reaction tube 203. Then, the gases are respectively ejected into the reaction tube 203 in the vicinity of the wafers 200 first through the gas supply holes 250a and the gas supply holes 250b of the nozzles 249a and 249b. Each of the gases ejected into the reaction tube 203 mainly flows in a direction parallel to the surfaces of the wafers 200, that is, in a horizontal direction. Thereby, it is possible to uniformly supply the gases to each of the wafers 200, and it is also possible to improve a thickness uniformity of a film formed on each of the wafers 200. After flowing over the surfaces of the wafers 200, the gas (for example, a residual gas remaining after the reaction) flows toward an exhaust port, that is, toward an exhaust pipe 231 described later. However, a flow direction of the residual gas may be determined appropriately depending on a location of the exhaust port, and is not limited to a vertical direction.

A source material (that is, a source gas) is supplied into the process chamber 201 through the gas supply pipe 232a provided with the MFC 241a and the valve 243a and the nozzle 249a.

A reactant (that is, a reactive gas) is supplied into the process chamber 201 through the gas supply pipe 232b provided with the MFC 241b and the valve 243b and the nozzle 249b. For example, an oxygen (O)-containing gas may be used as the reactive gas.

The inert gas is supplied into the process chamber 201 through the gas supply pipes 232c and 232d provided with the MFCs 241c and 241d and the valves 243c and 243d, respectively, and the nozzles 249a and 249b.

For example, a source gas supplier (which is a source gas supply structure or a source gas supply system) serving as a first gas supplier (which is a first gas supply structure or a first gas supply system) is constituted mainly by the gas supply pipe 232a, the MFC 241a and the valve 243a. The source gas supplier may also be referred to as a source material supplier (which is a source material supply structure or a source material supply system). A reactive gas supplier (which is a reactive gas supply structure or a reactive gas supply system) serving as a second gas supplier (which is a second gas supply structure or a second gas supply system) is constituted mainly by the gas supply pipe 232b, the MFC 241b and the valve 243b. The reactive gas supplier may also be referred to as a reactant supplier (which is a reactant supply structure or a reactant supply system). An inert gas supplier (which is an inert gas supply structure or an inert gas supply system) is constituted mainly by the gas supply pipes 232c and 232d, the MFCs 241c and 241d and the valves 243c and 243d. The source gas supplier, the reactive gas supplier and the inert gas supplier may be collectively referred to as a gas supplier (which is a gas supply structure or a gas supply system).

### <Substrate Support>

As shown in FIG. 1, a boat 217 (which serves as a substrate support or a substrate retainer capable of accommodating and supporting a plurality of wafers) is configured to accommodate (or support) the wafers 200 (for example, 25 wafers to 200 wafers) along the vertical direction while the wafers 200 are horizontally oriented with their centers aligned with one another with a predetermined interval therebetween in a multistage manner. For example, the boat 217 is made of a heat resistant material such as quartz and SiC. A plurality of heat insulating plates 218 horizontally oriented are provided under the boat 217 in a multistage manner. For example, each of the heat insulating plates 218 is made of a heat resistant material such as quartz and SiC. With such a configuration, the heat insulating plates 218 suppress a transmission of the heat from the heater 207 to a seal cap 219 described later. However, the present embodiments are not limited thereto. For example, instead of the heat insulating plates 218, a heat insulating cylinder (not shown) such as a cylinder made of a heat resistant material such as quartz and SiC may be provided under the boat 217.

### <Plasma Generator>

Subsequently, the plasma generator will be described with reference to FIGS. 1 to 4B.

The electrodes 300 for generating a plasma are provided outside the reaction tube 203, that is, outside the process vessel (process chamber 201). The electrodes 300 are configured such that, by applying an electric power to the electrodes 300, the gas inside the reaction tube 203 (that is, inside the process vessel (process chamber 201)) can be plasmatized and excited, that is, the gas can be excited into a plasma state. As shown in FIG. 2, by using a capacitively coupled plasma (abbreviated as CCP), the plasma is generated inside the reaction tube 203 (which is a vacuum partition made of a material such as quartz) when the reactive gas is supplied.

Specifically, as shown in FIG. 2, the electrodes 300 and the electrode fixture 301 configured to fix the electrodes 300 are arranged between the heater 207 and the reaction tube 203. As described above, the electrode fixture 301 is provided in the inner side of the heater 207, and the electrodes 300 are provided in the inner side of the electrode fixture 301. In addition, the reaction tube 203 is provided in the inner side of the electrodes 300.

In addition, as shown in FIGS. 1 and 2, each of the electrode 300 and the electrode fixture 301 is installed in an annular space provided between an inner wall of the heater 207 and an outer wall of the reaction tube 203 when viewed from above, and extends upward from the lower portion toward the upper portion of the reaction tube 203 along the outer wall of the reaction tube 203 (that is, extends upward along an arrangement direction (that is, the stacking direction) of the wafers 200). The electrodes 300 are provided in a manner parallel to the nozzles 249a and 249b. The electrodes 300 and the electrode fixture 301 are arranged to be aligned in a manner concentric with the reaction tube 203 and the heater 207 when viewed from above, and are not in contact with the heater 207. For example, the electrode fixture 301 is made of an insulating material (insulator). The electrode fixture 301 is provided so as to cover at least a part of the electrodes 300 and a part of the reaction tube 203. Therefore, the electrode fixture 301 may also be referred to as a “cover” (which is a quartz cover, an insulating wall or an insulating plate) or a “cover with an arc-shaped cross-section” (which is a structure with an arc-shaped cross-section or a wall with an arc-shaped cross-section).

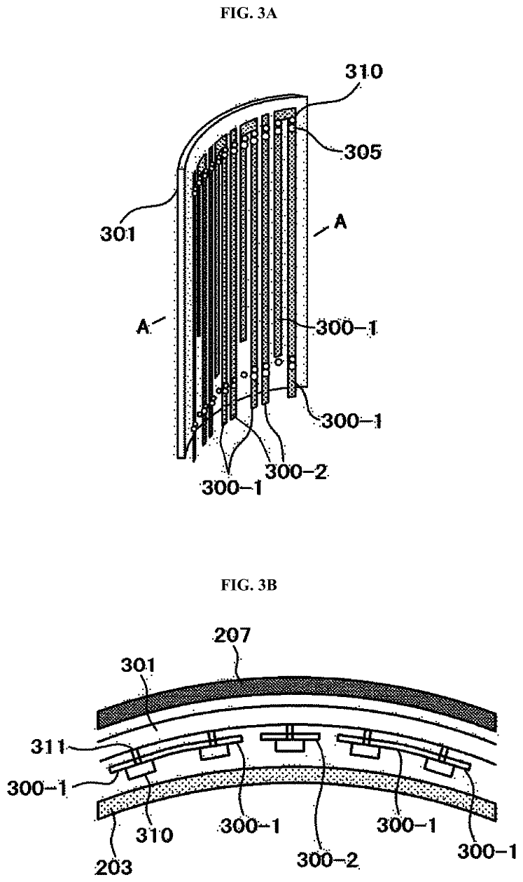

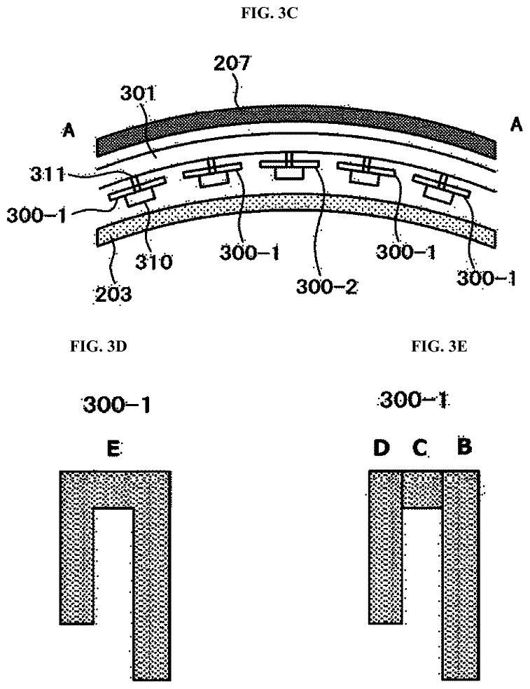

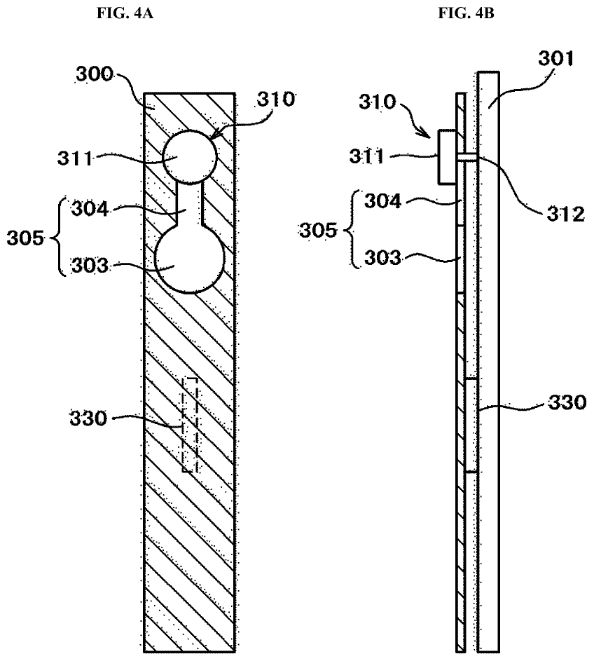

As shown in FIG. 2, the plurality of electrodes 300 are provided. The electrodes 300 are fixed and installed on an inner wall of the electrode fixture 301. More specifically, as shown in FIGS. 4A and 4B, a plurality of protrusions (which are hooks) 310 on which the electrodes 300 can be hooked are provided on a surface of the inner wall of the electrode fixture 301, and a plurality of openings 305 which are through-holes through which the protrusions 310 can be inserted are provided at the electrodes 300. The electrodes 300 can be fixed to the electrode fixture 301 by hooking the electrodes 300 on the protrusions 310 provided on the surface of the inner wall of the electrode fixture 301 through the openings 305. In FIGS. 3A through 3C, an example of fixing the electrode 300 at two locations or three locations (that is, two openings 305 or three openings 305 are provided for the electrode 300, and the electrode 300 is hooked at and fixed by the two protrusions 310 or the three protrusions 310) is shown. In FIG. 2, an example in which nine electrodes 300 are fixed to the electrode fixture 301 is shown. Further, in FIG. 2, for example, a pair of such configurations (structures) in which nine electrodes 300 are fixed to the electrode fixture 301 is provided. That is, two electrode fixtures including the electrode fixture 301 and another electrode fixture 301 are provided, nine electrodes 300 are fixed to the electrode fixture 301, and other nine electrodes 300 are fixed to the above-mentioned another electrode fixture 301. As shown in FIGS. 2, 3A, 3B and 3C, for example, a configuration in which four electrodes 300-1 (six electrodes 300-1 in the cross-section of FIG. 2) and four electrodes 300-2 are fixed to the electrode fixture 301 is provided. Hereinafter, the electrodes 300-1 may also be referred to as “primary electrodes 300-1”, and each of the primary electrodes 300-1 may also be referred to as a “primary electrode 300-1”. In addition, the electrodes 300-2 may also be referred to as “secondary electrodes 300-2”, and each of the secondary electrodes 300-2 may also be referred to as a “secondary electrode 300-2”.

For example, each of the electrodes 300 is made of an oxidation resistant material such as nickel (Ni). Each of the electrodes 300 may be made of a metal material such as SUS, aluminum (Al) and copper (Cu). However, when each of the electrodes 300 is made of the oxidation resistant material such as nickel (Ni), it is possible to suppress a deterioration of an electrical conductivity, and it is also possible to suppress a decrease in an efficiency of generating the plasma. For example, each of the electrodes 300 may also be made of a nickel alloy material to which aluminum (Al) is added. In such a case, an aluminum oxide film (AlO film) (which is an oxide film whose heat resistance is high and whose corrosion resistance is high) can be formed on an outermost surface of each of the electrodes 300. The AlO film formed on the outermost surface of each of the electrodes 300 acts as a protective film (which is a block film or a barrier film), and can suppress a progress of the deterioration inside each of the electrodes 300. Thereby, it is possible to further suppress the decrease in the efficiency of generating the plasma due to a decrease in the electrical conductivity of each of the electrodes 300. The electrode fixture 301 is made of an insulating material (insulator), for example, a heat resistant material such as quartz and SiC. It is preferable that the material of the electrode fixture 301 is the same as that of the reaction tube 203.

As shown in FIG. 2 and FIGS. 3A to 3E, each of the electrodes 300 is configured as a thin plate (flat plate) of a rectangular shape or of an inverted U-shape elongated in the arrangement direction of the wafers 200. Each of the electrodes 300 may include: the primary electrodes (also referred to as “first electrodes” or “hot electrodes”) 300-1 connected to a high frequency power supply 320 via a matcher (which is a matching structure: not shown); and the secondary electrodes (also referred to as “second electrodes” or “ground electrodes”) 300-2 which are grounded to earth with a reference potential of 0 V. The primary electrodes 300-1 and the secondary electrodes 300-2 are arranged at an equal interval on the cross-section taken along the line A-A as shown in FIGS. 2 and 3C. By applying a high frequency power from the high frequency power supply 320 via the matcher between the primary electrode (hot electrode) 300-1 and the secondary electrode (ground electrode) 300-2, the plasma is generated in a region between the primary electrode 300-1 and the secondary electrode 300-2. The region where the plasma is generated may also be referred to as a “plasma generation region”. As shown in FIG. 1, the electrodes 300 (that is, the primary electrodes 300-1 and the secondary electrodes 300-2) are arranged in a direction perpendicular to the process vessel (that is, the vertical direction or the stacking direction of the wafers 200). In addition, as shown in FIGS. 2 to 3C, the electrodes 300 are arranged in an arc shape on the cross-section taken along the line A-A at an equal interval when viewed from above. That is, the electrodes 300 are arranged such that a distance (gap) between every two adjacent electrodes among the electrodes 300 is substantially the same. Further, the electrodes 300 are arranged in a substantially arc shape between the reaction tube 203 and the heater 207 along the outer wall of the reaction tube 203 when viewed from above. For example, the electrodes 300 are arranged on and fixed to the surface of the inner wall of the electrode fixture 301 (which is formed in an arc shape with a central angle of 30 degrees or more and 240 degrees or less, for example). In addition, as described above, the electrodes 300 are provided in a manner parallel to the nozzles 249a and 249b.

As shown in FIGS. 3A, 3D and 3E, the primary electrode (hot electrode) 300-1 of the inverted U-shape may be regarded as a flat electrode structure in which upper portions of two or more electrode segments (hot electrode segments) of different lengths are electrically connected to each other. A longitudinal direction of each of the primary electrode (hot electrode) 300-1 and the secondary electrode (ground electrode) 300-2 is same as the stacking direction of the wafers 200.

As shown in FIG. 3D, the primary electrode (hot electrode) 300-1 of the inverted U-shape may be formed as a single body in a flat plate shape E. Alternatively, as shown in FIG. 3E, the primary electrode (hot electrode) 300-1 of the inverted U-shape may be formed as a separably assembled structure in which two flat plate structures (vertical structures) B and D of different lengths are connected to each other by an upper structure (connecting structure) C of a flat plate shape. In other words, it may be regarded that the primary electrode (hot electrode) 300-1 of the inverted U-shape includes a folded structure (folded portion) of a U-shape in which two or more electrode segments (hot electrode segments) such as the two flat plate structures (vertical structures) B and D of different lengths are connected to each other by using the upper structure (connecting structure) C. With such a separably assembled structure, it is possible to easily adjust a plasma electric field by changing the length of the shorter one of the flat plate structures, that is, the length of “the other” electrode segment of the primary electrode (hot electrode) 300-1 of the inverted U-shape, which is described later.

In addition, the primary electrode (hot electrode) 300-1 of the inverted U-shape is configured to be folded back at its upper portion in a direction opposite to the stacking direction of the wafers 200. The primary electrodes (hot electrodes) 300-1 connected to the high frequency power supply 320 and folded back at their upper portions, the secondary electrodes (ground electrodes) 300-2 which are grounded to the reference potential of 0 V and the electrode fixture 301 may be collectively referred to as an “electrode structure” or an “electrode assembly”. As shown in FIG. 2, the electrode structure is preferably arranged at a location that can avoid a contact with the nozzles 249a and 249b and the exhaust pipe 231. FIG. 2 is a diagram schematically illustrating an example in which two electrode structures are arranged to face each other via centers of the wafers 200 (that is, the center of the reaction tube 203) interposed therebetween while avoiding the contact with the nozzles 249a and 249b and the exhaust pipe 231. In the example shown in FIG. 2, the two electrode structures are arranged line-symmetrically when viewed from above (that is, the two electrode structures are arranged symmetrically with each other). By arranging the two electrode structures as described above, it is possible to arrange the nozzles 249a and 249b, a temperature sensor 263 and the exhaust pipe 231 outside the plasma generation region in the process chamber 201. Thereby, it is possible to suppress a plasma damage to components (such as the nozzles 249a and 249b, the temperature sensor 263 and the exhaust pipe 231), a wear and tear of the components and a generation of particles from the components.

As shown in FIG. 3A, the secondary electrode (ground electrode) 300-2 is also configured as a flat electrode structure. The length of one electrode segment of the primary electrode (hot electrode) 300-1 of the inverted U-shape is substantially the same as a length of the secondary electrode (ground electrode) 300-2. The length of the other electrode segment of the primary electrode (hot electrode) 300-1 of the inverted U-shape is shorter than the length of the secondary electrode (ground electrode) 300-2. In addition, a sum of the length of the one electrode segment and the length of the other electrode segment of the primary electrode (hot electrode) 300-1 of the inverted U-shape is set to be longer than the length of the secondary electrode (ground electrode) 300-2. A lower portion of the longer one of the electrode segments of the primary electrode (hot electrode) 300-1 of the inverted U-shape is connected to the high frequency power supply 320 via the matcher (not shown).

As shown in FIG. 3A, from the right to the left of FIG. 3A, there are provided a first one among the primary electrodes (hot electrodes) 300-1 of the inverted U-shape, a first one among the secondary electrodes (ground electrodes) 300-2, a second one among the primary electrodes (hot electrodes) 300-1 of the inverted U-shape, a second one among the secondary electrodes (ground electrodes) 300-2, a third one among the primary electrodes (hot electrodes) 300-1 of the inverted U-shape, a third one among the secondary electrodes (ground electrodes) 300-2, a fourth one among the primary electrodes (hot electrodes) 300-1 of the inverted U-shape and a fourth one among the secondary electrodes (ground electrodes) 300-2. In other words, the secondary electrode (ground electrode) 300-2 is arranged between the primary electrodes (hot electrodes) 300-1 of the inverted U-shape. In other words, the primary electrodes (hot electrodes) 300-1 of the inverted U-shape are arranged alternately with the secondary electrodes (ground electrodes) 300-2. That is, when viewed from the cross-section taken along the line A-A, the primary electrodes 300-1 of the inverted U-shape are arranged alternately with the secondary electrodes 300-2. Therefore, as shown in FIG. 3A, the number of the primary electrodes 300-1 of the inverted U-shape is the same as the number of the secondary electrodes 300-2.

In addition, as shown in FIG. 3A, in the first one to the fourth one among the primary electrodes (hot electrodes) 300-1 of the inverted U-shape, the length of “the other” electrode segment of the first one, the length of “the other” electrode segment of the second one, the length of “the other” electrode segment of the third one and the length of “the other” electrode segment of the fourth one among the primary electrodes (hot electrodes) 300-1 of the inverted U-shape are set to be different from one another. As a result, an area of the first one, an area of the second one, an area of the third one and an area of the fourth one among the primary electrodes (hot electrodes) 300-1 of the inverted U-shape are different from one another.

In the present embodiments, unless they need to be distinguished separately, the primary electrodes (hot electrodes) 300-1 and the secondary electrodes (ground electrodes) 300-2 will be described as the electrodes 300.

As shown in FIG. 2, as described above, the electrodes 300 (that is, the primary electrodes 300-1 and the secondary electrodes 300-2) are arranged, when viewed from above, in a substantially arc shape between the reaction tube 203 and the heater 207 (that is, inside of the heater 207 and outside of the reaction tube 203) along the outer wall of the reaction tube 203. For example, the electrodes 300 are arranged on and fixed to the surface of the inner wall of the electrode fixture 301 (quartz cover) which is formed in an arc shape with the central angle of 30 degrees or more and 240 degrees or less, for example. In the present embodiments, for example, when the central angle is less than 30 degrees, a generation amount of the plasma may be reduced. For example, when the central angle is more than 240 degrees, a thermal energy from the heater 207 may be blocked, and thereby, a substrate processing (that is, a processing of the wafers 200) may be adversely affected. In addition, when the central angle is more than 240 degrees, it may be difficult to arrange the nozzles 249a and 249b and the temperature sensor 263 such as a cascade TC (thermocouple) to avoid the plasma generation region. When the nozzles 249a and 249b and the like are arranged in the plasma generation region, the particles (PC) are more likely to be generated from the nozzles 249a and 249b and the like. In addition, when the cascade TC is also arranged in the plasma generation region, a discharge may occur from a line of the cascade TC, and thereby, a damage to the wafer 200 may occur and a non-uniformity in the film may occur. Therefore, by setting the central angle to be between 30 degrees and 240 degrees, it is possible to perform the substrate processing (wafer processing) while ensuring the generation amount of the plasma and suppressing a blocking of the thermal energy from the heater 207.

For example, the plasma (active species) 302 is generated in the reaction tube 203 by inputting a high frequency power of 25 MHz or more and 35 MHz or less (more specifically, a high frequency power of 27.12 MHz) to the electrodes 300 from the high frequency power supply 320 via the matcher (not shown). By using the plasma 302 generated in such a manner described above, it is possible to supply the plasma 302 for the substrate processing to the surfaces of the wafers 200 from the peripheries of the wafers 200. The high frequency power is supplied through lower portions (lower ends) of the electrodes 300. For example, the plasma generator is constituted mainly by the electrodes 300 and the high frequency power supply 320. The plasma generator may further include the matcher (not shown) and the electrode fixture 301 serving as the electrode fixing jig.

In addition, as shown in FIG. 4A, in the electrode 300, a cutout structure serving as the openings 305 is provided. Hereinafter, the cutout structure serving as the openings 305 may also be referred to as a “cutout structure 305”. For example, the cutout structure 305 is constituted by: a circular cutout 303 through which a protrusion head 311 (described later) passes; and a slide cutout 304 through which a protrusion shaft 312 slides.

Preferably, a thickness of each of the electrodes 300 is set to 0.1 mm or more and 1 mm or less and a width of each of the electrodes 300 is set to 5 mm or more and 30 mm or less such that a strength of each of the electrodes 300 is sufficient and an efficiency of heating the wafers 200 by a heat source such as the heater 207 is not significantly lowered. For example, in FIG. 2 or FIG. 3C, the thickness of each of the electrodes 300 (for example, a thickness of the secondary electrode (ground electrode) 300-2 or a thickness of each of the two electrode segments (of different lengths) of the primary electrode (hot electrode) 300-1 of the inverted U-shape) can be set to 0.1 mm or more and 1 mm or less and the width of each of the electrodes 300 can be set to 5 mm or more and 30 mm or less. In addition, it is preferable that each of the electrodes 300 is of a bending structure serving as a deformation suppressing structure (which prevents a deformation due to the heating by the heater 207). In such a case, since the electrodes 300 are arranged between the reaction tube 203 (made of quartz) and the heater 207, it is preferable that a bending angle of the bending structure is set to 90 degrees or more and 175 degrees or less by considering space restrictions. A cover film may be formed on surfaces of the electrodes 300 by a thermal oxidation, and a thermal stress may cause the cover film to peel off and to generate the particles. Therefore, it is preferable not to bend the bending structure too much.

According to the present embodiments, for example, the plasma of a CCP mode is generated by using the substrate processing apparatus such as a vertical type substrate processing apparatus in which a frequency of the high frequency power supply 320 is set to 27.12 MHz, a width of each of the electrodes 300 is set to 10 mm, and a thickness of each of the electrodes 300 is set to 1 mm. As shown in FIG. 3C, on the outer wall of the reaction tube 203 of a tubular shape, for example, the primary electrodes 300-1 to which a desirable potential is applied and the secondary electrodes 300-2 to which the reference potential is applied are arranged with an electrode pitch (that is, a center-to-center distance) of 20 mm when generating the plasma of the CCP mode. For example, a first one of the primary electrodes 300-1, a second one of the primary electrodes 300-1, a first one of the secondary electrodes 300-2, a third one of the primary electrodes 300-1, a fourth one of the primary electrodes 300-1 and so on are arranged sequentially in this order. That is, the electrodes 300 are formed by two primary electrodes 300-1 being arranged in succession as a pair, and the secondary electrode 300-2 is interposed between two pairs of the primary electrodes 300-1. For example, the length of the one electrode segment of the primary electrode (hot electrode) 300-1 of the inverted U-shape and the length of the secondary electrode 300-2 are set to be 1 m. For example, the length of the other electrode segment among the electrodes in the primary electrode (hot electrode) 300-1 of the inverted U-shape is set to less than 1 m.

When a loading range of the wafers 200 in the boat 217 is set to 8% or more of an output wavelength of the high frequency power supply 320, a variation (difference) may occur in a density distribution of the plasma 302 (also referred to as a “distribution of the plasma 302”) due to an uneven voltage distribution of a standing wave (cosine curve) generated by a superposition of a forward wave and a reflected wave in the vertical direction of the electrode 300. Therefore, a non-uniformity may occur between the wafers 200 in a thickness of the film and a quality of the film, which are correlated with the density distribution of the plasma 302. For example, when the length of the electrode 300 in a wafer placement region is greater than a certain value (about 1/10 of the wavelength), an effect of the standing wave may become significant, and a plasma density at the top (upper portion) of the electrode 300 may be higher than a plasma density at the bottom (lower portion) of the electrode 300. Thereby, the variation may occur in the distribution of the plasma 302 along the vertical direction.

In order to address such a problem mentioned above, since a reflection coefficient changes by adjusting the length of a front end (tip) of the electrode 300, a method of shifting the voltage distribution of the standing wave in a wafer region (that is, the wafer placement region) downward by changing a phase difference between the forward wave and the reflected wave may be used. By using such a method, it is possible to reduce a variation (bias) in the voltage distribution. As a result, it is possible to ensure a uniform density distribution of the plasma 302, and it is also possible to improve a uniformity of the thickness of the film or a uniformity of the quality of the film between the wafers 200.

According to the present embodiments, in order to eliminate the variation in the distribution of the plasma 302, a shape (length or area) of the primary electrode (hot electrode) 300-1 is adjusted to uniformize the distribution of the plasma 302 in the wafer placement region (that is, a placement region for the wafers 200) in the vertical direction.

Features of the electrode 300 are summarized as follows.
(a) As described above, the primary electrode (hot electrode) 300-1 includes the folded structure (folded portion) at its upper portion. As a result, a high voltage from the front end (tip) thereof and a strong electric field can be provided. A length of the folded structure is adjusted such that the front end (tip) is located in a location where the electric field is weak.
(b) The plurality of primary electrodes (hot electrodes) 300-1 configured to be folded back at the upper portions thereof and the plurality of secondary electrodes (ground electrodes) 300-2 are provided.
(c) The secondary electrodes (ground electrodes) 300-2 are arranged between the primary electrodes (hot electrodes) 300-1.
(d) The primary electrodes (hot electrodes) 300-1 and the secondary electrodes (ground electrodes) 300-2 are arranged alternately.
(e) The ratio between the number of the primary electrodes (hot electrodes) 300-1 and the number of the secondary electrodes (ground electrodes) 300-2 is 1:1 (that is, the numbers are the same).
(f) For example, the area of the primary electrode (hot electrode) 300-1 is 1.5 times or more the area of the secondary electrode (ground electrode) 300-2.
(g) Each of the primary electrodes (hot electrodes) 300-1 include two or more types of electrodes or electrode segments with different lengths or different areas.

In the present embodiments, a pressure (inner pressure) of a furnace (that is, the process furnace 202) when the substrate processing is performed may be preferably controlled within a range of 2 Pa or more and 300 Pa or less. When the inner pressure of the furnace is lower than 2 Pa, a mean free path of gas molecules becomes longer than the Debye length of the plasma, and the plasma directly hitting a wall of the furnace becomes noticeable. As a result, it may be difficult to suppress the generation of the particles. In addition, when the inner pressure of the furnace is higher than 300 Pa, the efficiency of generating the plasma is saturated so that the generation amount of the plasma does not change even when the reactive gas is supplied. Thereby, the reactive gas may be wasted. In addition, since the mean free path of the gas molecules is shortened, a transport efficiency of the active species of the plasma to the wafers 200 may deteriorate.

### <Electrode Fixing Jig>

Subsequently, the electrode fixture 301 serving as the electrode fixing jig capable of fixing the electrodes 300 will be described with reference to FIGS. 3A to 4B. As shown in FIGS. 3A, 3B, 3C, 4A and 4B, the electrodes 300 are fixed by hooking the cutout structure 305 thereof into the protrusions 310 provided on the surface of the inner wall of the electrode fixture 301 (which is a curved fixing jig) and sliding the electrodes 300 until the electrodes 300 are installed on an outer periphery of the reaction tube 203 so as to be integrated with the electrode fixture 301 as a single body (hook-type electrode assembly). According to the present embodiments, the electrodes 300 and the electrode fixture 301 serving as the electrode fixing jig may be collectively referred to as an “electrode fixing configuration” or an “electrode fixing assembly”. For example, the electrode fixture 301 is made of quartz, and each of the electrodes 300 is made of the nickel alloy.

Preferably, a thickness of the electrode fixture 301 is set to 1 mm or more and 5 mm or less such that a strength of the electrode fixture 301 is sufficient and the efficiency of heating the wafers 200 by the heater 207 is not significantly lowered. When the thickness of the electrode fixture 301 is less than 1 mm, it becomes impossible to obtain a desired strength against the own weight of the electrode fixture 301 or a desired resistance against a temperature change. When the thickness of the electrode fixture 301 is more than 5 mm, the electrode fixture 301 absorbs the thermal energy radiated from the heater 207 so that a heat treatment process for the wafers 200 cannot be properly performed.

In addition, the electrode fixture 301 is provided with the plurality of protrusions 310 serving as tack-shaped fixing jigs capable of fixing the electrodes 300 on the surface of the inner wall of the electrode fixture 301 facing the reaction tube 203. Each of the protrusions 310 is constituted by the protrusion head 311 and the protrusion shaft 312. A maximum width of the protrusion head 311 is set to be smaller than a diameter of the circular cutout 303 of the cutout structure 305 of the electrode 300, and a maximum width of the protrusion shaft 312 is set to be smaller than a width of the slide cutout 304. The cutout structure 305 of the electrode 300 is of a keyhole-like shape, the slide cutout 304 is capable of guiding the protrusion shaft 312 while the electrode 300 is slid therealong, and the protrusion head 311 is configured so as not to fall out of (or come off) the slide cutout 304. In other words, it can be said that the electrode fixture 301 includes a fixing structure (fixing portion) provided with the protrusion head 311 serving as a front end portion capable of preventing the electrodes 300 from slipping out of the protrusion shaft 312 (which is a columnar structure with which the electrodes 300 are engaged). In addition, it is apparent that shapes of the cutout structure 305 and the protrusion head 311 described above are not limited to the shapes shown in FIGS. 3A to 4B as long as the electrodes 300 are capable of being engaged with the electrode fixture 301. For example, the protrusion head 311 may be of a convex shape such as a hammer shape and a thorn shape.

In order to maintain a constant distance between the electrode fixture 301 (or the reaction tube 203) and each of the electrodes 300, the electrode fixture 301 or the electrodes 300 may be provided with an elastic structure such as a spacer and a spring interposed between them, or the elastic structure may be integrated with the electrode fixture 301 or the electrodes 300 as a single body. According to the present embodiments, a spacer 330 as shown in FIG. 4B is integrated with the electrode fixture 301 as a single body. It is effective to provide a plurality of spacers including the spacer 330 for each of the electrodes 300 in order to maintain the constant distance between the electrode fixture 301 and each of the electrodes 300.

In order to obtain a high substrate processing capability at a substrate temperature of 500° C. or less, it is preferable that the electrode fixture 301 is of a substantially arc shape with a central angle of 30° or more and 240° or less. In addition, in order to avoid the generation of the particles, it is preferable that the electrode fixture 301 is arranged to avoid a contact with the exhaust pipe 231 serving as the exhaust port and the nozzles 249a and 249b. In other words, the electrode fixture 301 serving as the electrode fixing jig is arranged on the outer periphery of the reaction tube 203 other than locations where the nozzles 249a and 249b serving as a part of the gas supplier and the exhaust pipe 231 serving as a part of an exhauster are installed in the reaction tube 203. According to the present embodiments, for example, two electrode fixtures 301 with a central angle of 110° are installed symmetrically.

### <Spacer>

Subsequently, the spacer 330 for fixing each of the electrodes 300 to a surface of the electrode fixture 301 serving as the electrode fixing jig (or to the outer wall of the reaction tube 203) with the constant distance therebetween will be described with reference to FIGS. 4A and 4B. For example, the spacer 330 is made of quartz material of a cylindrical shape, and is integrated with the electrode fixture 301 as a single body. By bringing the spacer 330 into contact with the electrodes 300, the electrodes 300 are fixed to the electrode fixture 301. As long as the electrodes 300 can be fixed to the electrode fixture 301 (or the reaction tube 203) with the constant distance therebetween, the spacer 330 can be integrated with either the electrodes 300 or the electrode fixture 301 as a single body regardless of its shape. For example, the spacer 330 may be made of a quartz material of a semi-cylindrical shape and integrated with the electrode fixture 301 as a single body to fix the electrodes 300. Alternatively, the spacer 330 may be made of a metal material such as SUS and integrated with the electrodes 300 as a single body to fix the electrodes 300. Since the electrode fixing jig and the spacer are provided on the quartz cover, it is possible to easily determine positions of the electrodes 300, and the electrodes 300 can be selectively replaced when the electrodes 300 deteriorates. Therefore, it is possible to reduce a maintenance cost. In addition, the spacer 330 generates a pressing force in a direction of the protrusion head 311 serving as the front end portion, via a contact surface with the electrodes 300, it is possible to prevent the electrode 300 from falling out of (or coming off) the electrode fixture 301. For example, the spacer 330 may be included in the electrode fixing configuration described above.

### <Exhauster>

As shown in FIG. 1, the exhaust pipe 231 through which an atmosphere (inner atmosphere) of the process chamber 201 is exhausted is provided at the reaction tube 203. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (which is a pressure detection structure) to detect a pressure (inner pressure) of the process chamber 201, and the APC valve 244 serves as an exhaust valve (which is a pressure regulator). With the vacuum pump 246 in operation, the APC valve 244 may be opened or closed to perform a vacuum exhaust of the process chamber 201 or stop the vacuum exhaust. Further, with the vacuum pump 246 in operation, an opening degree of the APC valve 244 may be adjusted based on pressure information detected by the pressure sensor 245, in order to control (or adjust) the inner pressure of the process chamber 201. The exhauster (which is an exhaust structure or an exhaust system) is constituted mainly by the exhaust pipe 231, the APC valve 244 and the pressure sensor 245. The exhauster may further include the vacuum pump 246. However, the present embodiments are not limited to an example in which the exhaust pipe 231 is provided at the reaction tube 203. For example, similar to the nozzles 249a and 249b, the exhaust pipe 231 may be provided at the manifold 209 instead of the reaction tube 203.

### <Peripheral Components>

The seal cap 219 serving as a furnace opening lid capable of airtightly sealing (or closing) a lower end opening of the manifold 209 is provided under the manifold 209. The seal cap 219 is in contact with the lower end of the manifold 209 from thereunder. For example, the seal cap 219 is made of a metal material such as SUS, and is of a disk shape. An O-ring 220b serving as a seal is provided on an upper surface of the seal cap 219 so as to be in contact with the lower end of the manifold 209.

A rotator (which is a rotating structure) 267 capable of rotating the boat 217 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the reaction tube 203. When the seal cap 219 is elevated or lowered in the vertical direction by the boat elevator 115, the boat 217 can be transferred (loaded) into the process chamber 201 or transferred (unloaded) out of the process chamber 201.

The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201. In addition, a shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. Similar to the nozzles 249a and 249b, the temperature sensor 263 is provided along the inner wall of the reaction tube 203.

### <Controller>

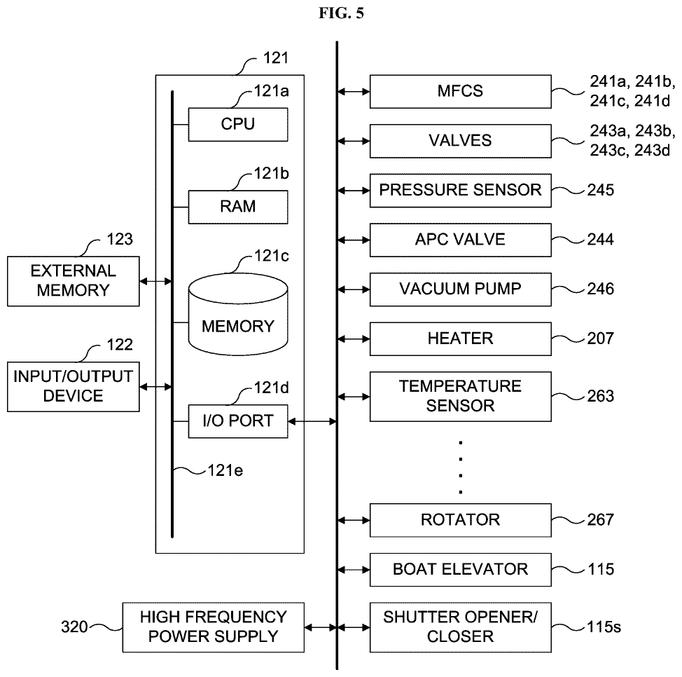

Subsequently, a controller 121 will be described with reference to FIG. 5. FIG. 5 is a block diagram schematically illustrating an exemplary configuration of the controller 121 and related components of the substrate processing apparatus shown in FIG. 1. As shown in FIG. 5, the controller 121 serving as a control structure (or a control apparatus) is constituted by a computer including a CPU (Central Processing Unit) 121a, a RAM (Random Access Memory) 121b, a memory 121c and an I/O port 121d. The RAM 121b, the memory 121c and the I/O port 121d are configured to exchange data with the CPU 121a through an internal bus 121e. For example, an input/output device 122 constituted by a component such as a touch panel is connected to the controller 121.

For example, the memory 121c is configured by a component such as a flash memory and a hard disk drive (HDD). For example, a control program configured to control an operation of the substrate processing apparatus or a process recipe containing information on procedures and conditions of a film-forming process (that is, the substrate processing) described later is readably stored in the memory 121c. The process recipe is obtained by combining steps (procedures) of various processes such as the film-forming process described later such that the controller 121 can execute the steps to acquire a predetermined result, and functions as a program. Hereafter, the process recipe and the control program may be collectively or individually referred to as a “program”. In addition, the process recipe may also be simply referred to as a “recipe”. Thus, in the present specification, the term “program” may refer to the recipe alone, may refer to the control program alone, or may refer to both of the recipe and the control program. The RAM 121b functions as a memory area (work area) where a program or data read by the CPU 121a is temporarily stored.

The I/O port 121d is connected to the above-described components such as the MFCs 241a through 241d, the valves 243a through 243d, the pressure sensor 245, the APC valve 244, the vacuum pump 246, the heater 207, the temperature sensor 263, the rotator 267, the boat elevator 115, the shutter opener/closer 115s and the high frequency power supply 320.

The CPU 121a is configured to read the control program from the memory 121c and execute the control program. In addition, the CPU 121a is configured to read the recipe from the memory 121c in accordance with an operation command inputted from the input/output device 122. In accordance with the contents of the recipe read from the memory 121c, the CPU 121a is configured to control various operations such as a control operation of the rotator 267, flow rate adjusting operations for various gases by the MFCs 241a through 241d, opening and closing operations of the valves 243a through 243d, an opening and closing operation of the APC valve 244, a pressure adjusting operation by the APC valve 244 based on the pressure sensor 245, a start and stop of the vacuum pump 246, a temperature adjusting operation by the heater 207 based on the temperature sensor 263, operations of adjusting a forward rotation and a reverse rotation, a rotation angle and a rotation speed of the boat 217 by the rotator 267, an elevating and lowering operation of the boat 217 by the boat elevator 115, an opening and closing operation of the shutter 219s by the shutter opener/closer 115s and a power supply operation of the high frequency power supply 320.

The controller 121 may be embodied by installing the above-described program stored in an external memory 123 into the computer. For example, the external memory 123 may include a magnetic disk such as a hard disk, an optical disk such as a CD, a magneto-optical disk such as an MO and a semiconductor memory such as a USB memory. The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication structure such as the Internet and a dedicated line may be used for providing the program to the computer.

### (2) Substrate Processing

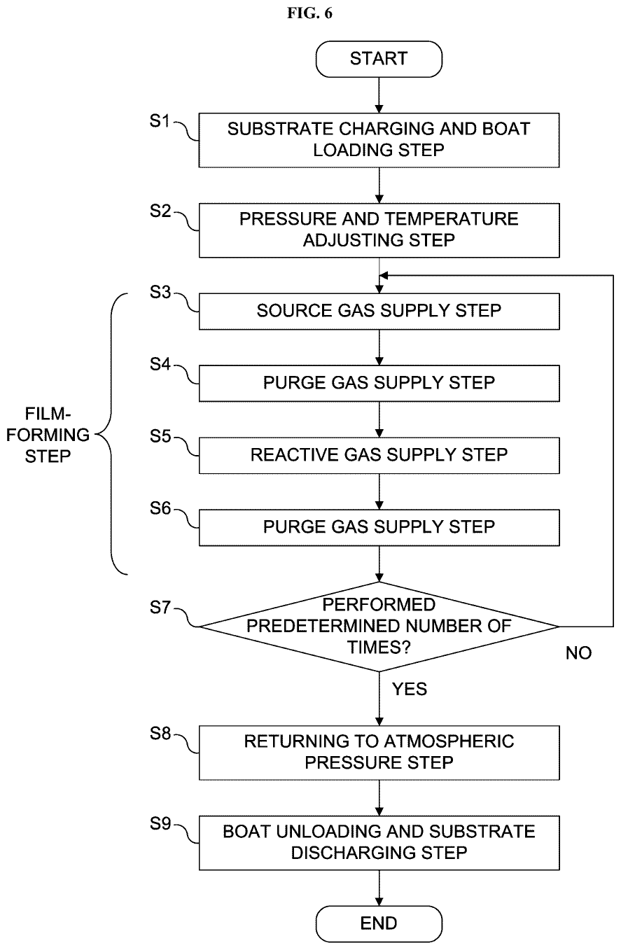

Hereinafter, the substrate processing (that is, the film-forming process) of forming a film on the substrate (that is, the wafer 200) by using the substrate processing apparatus described above, which is a part of a manufacturing process of a semiconductor device, will be described with reference to FIG. 6. FIG. 6 is a flow chart schematically illustrating an example of the substrate processing performed by using the substrate processing apparatus shown in FIG. 1. In the following descriptions, operations of components constituting the substrate processing apparatus are controlled by the controller 121.

In the present specification, a process flow of the film-forming process shown in FIG. 6 may be illustrated as follows.

$$( Source gas \to Reactive gas ) \times n$$

### <Substrate Charging and Boat Loading Step: S1>

After the wafers 200 are charged (or transferred) into the boat 217 (substrate charging step), the shutter 219s is moved by the shutter opener/closer 115s to open the lower end opening of the manifold 209 (shutter opening step). Then, as shown in FIG. 1, the boat 217 charged with the wafers 200 is elevated by the boat elevator 115 and loaded (or transferred) into the process chamber 201 (boat loading step). With the boat 217 loaded, the seal cap 219 seals the lower end of the manifold 209 via the O-ring 220b.

### <Pressure and Temperature Adjusting Step: S2>

In the present step, the vacuum pump 246 vacuum-exhausts (decompresses and exhausts) the process chamber 201 such that the inner pressure of the process chamber 201 reaches and is maintained at a desired pressure (vacuum degree). When vacuum-exhausting the process chamber 201, the inner pressure of the process chamber 201 is measured by the pressure sensor 245, and the APC valve 244 is feedback-controlled based on the pressure information measured by the pressure sensor 245 (pressure adjusting step). The vacuum pump 246 continuously vacuum-exhausts the process chamber 201 until at least a film-forming step described later is completed.

In addition, the heater 207 heats the process chamber 201 such that the inner temperature of the process chamber 201 reaches and is maintained at a desired temperature. When heating the process chamber 201, the state of electric conduction to the heater 207 is feedback-controlled based on the temperature information detected by the temperature sensor 263 such that the desired temperature distribution of the inner temperature of the process chamber 201 is obtained (temperature adjusting step). The heater 207 continuously heats the process chamber 201 until at least the film-forming step described later is completed. However, when the film-forming step is performed at a temperature equal to or lower than the room temperature, the heating of the process chamber 201 by the heater 207 may be omitted. Further, when the substrate processing including the film-forming step is performed only at the temperature equal to or lower than the room temperature, the heater 207 may be omitted and the substrate processing apparatus may be implemented without the heater 207. In such a case, it is possible to simplify a configuration of the substrate processing apparatus.

Then, the rotator 267 starts rotating the boat 217 and the wafers 200 accommodated in the boat 217. The rotator 267 continuously rotates the boat 217 and the wafers 200 accommodated in the boat 217 until at least the film-forming step described later is completed.

### <Film-Forming Step: S3, S4, S5 and S6>

Thereafter, the film-forming step is performed by performing a cycle including a source gas supply step S3, a purge gas supply step S4, a reactive gas supply step S5 and a purge gas supply step S6 sequentially in this order.

### <Source Gas Supply Step S3 and Purge Gas Supply Step S4>

In the source gas supply step S3, the source gas is supplied onto the wafers 200 in the process chamber 201.

The valve 243a is opened to supply the source gas into the gas supply pipe 232a. After a flow rate of the source gas is adjusted by the MFC 241a, the source gas whose flow rate is adjusted is supplied into the process chamber 201 through the nozzle 249a and the gas supply holes 250a, and is exhausted through the exhaust pipe 231. Thereby, the source gas is supplied onto the wafers 200. Simultaneously with a supply of the source gas, the valve 243c may be opened to supply the inert gas into the gas supply pipe 232c. After a flow rate of the inert gas is adjusted by the MFC 241c, the inert gas whose flow rate is adjusted is supplied together with the source gas into the process chamber 201, and is exhausted through the exhaust pipe 231.

In order to prevent the source gas from entering the nozzle 249b, the valve 243d may be opened to supply the inert gas into the gas supply pipe 232d. The inert gas is supplied into the process chamber 201 through the gas supply pipe 232d and the nozzle 249b, and is exhausted through the exhaust pipe 231.

For example, process conditions of the present step are as follows:

A process temperature: from the room temperature (25° C.) to 550° C., preferably from 400° C. to 500° C.;

A process pressure: from 1 Pa to 4,000 Pa, preferably from 100 Pa to 1,000 Pa;

A supply flow rate of the source gas: from 0.1 slm to 3 slm;

A supply time (time duration) of supplying the source gas: from 1 second to 100 seconds, preferably from 1 second to 50 seconds; and A supply flow rate of the inert gas (for each gas supply pipe): from 0 slm to 10 slm.

Further, in the present specification, a notation of a numerical range such as “from 25° C. to 550° C.” means that a lower limit and an upper limit are included in the numerical range. Therefore, for example, a numerical range “from 25° C. to 550° C.” means a range equal to or higher than 25° C. and equal to or lower than 550° C. The same also applies to other numerical ranges described herein. For example, in the present specification, the process temperature refers to a temperature of the wafer 200 or the inner temperature of the process chamber 201, and the process pressure refers to the inner pressure of the process chamber 201. Further, when the supply flow rate of the gas is 0 slm, it means a case where the gas is not supplied. The same also applies to the following description.

By supplying the source gas onto the wafer 200 in accordance with the process conditions described above, a first layer is formed on the wafer 200 (that is, on a base film formed on the surface of the wafer 200). For example, when a silicon (Si)-containing gas described later is used as the source gas, a silicon-containing layer is formed on the wafer 200 as the first layer.

After the first layer is formed in the step S3, the valve 243a is closed to stop the supply of the source gas into the process chamber 201. With the APC valve 244 open, the vacuum pump 246 vacuum-exhausts the inner atmosphere of the process chamber 201 to remove a residual gas remaining in the process chamber 201 such as the source gas which did not react or which contributed to a formation of the first layer and reaction by-products from the process chamber 201 (step S4). In addition, by opening the valves 243c and 243d, the inert gas is supplied into the process chamber 201. The inert gas serves as a purge gas.

As the source gas, for example, an aminosilane-based gas such as tetrakis (dimethylamino) silane (Si[N(CH₃)₂]₄) gas, tris (dimethylamino) silane (Si[N(CH₃)₂]₃H) gas, bis(dimethylamino) silane (Si[N(CH₃)₂]₂H₂) gas, bis (diethylamino) silane (Si[N(C₂H₅)₂]₂H₂) gas, bis (tertiarybutylamino) silane gas (SiH₂[NH(C₄H₉)]₂) gas and (diisopropylamino) silane (SiH₃[N(C₃H₇)₂]) gas may be used. For example, one or more of the gases exemplified above as the aminosilane-based gas may be used as the source gas.

As the source gas, for example, a chlorosilane-based gas such as monochlorosilane (SiH₃Cl) gas, dichlorosilane (SiH₂Cl₂) gas, trichlorosilane (SiHCl₃) gas, tetrachlorosilane (SiCl₄) gas, hexachlorodisilane (Si₂Cl₆) gas and octachlorotrisilane (Si₃Cl₈) gas may be used. In addition, as the source gas, for example, a fluorosilane-based gas such as tetrafluorosilane (SiF₄) gas and difluorosilane (SiH₂F₂) gas, a bromosilane-based gas such as tetrabromosilane (SiBr₄) gas and dibromosilane (SiH₂Br₂) gas, or an iodine silane-based gas such as tetraiodide silane (SiI₄) gas and diiodosilane (SiH₂I₂) gas may be used. That is, a halosilane-based gas may be used as the source gas. For example, one or more of the gases exemplified above as the halosilane-based gas may be used as the source gas.

As the source gas, for example, a silicon hydride gas such as monosilane (SiH₄) gas, disilane (Si₂H₆) gas and trisilane (Si₃H₈) gas may be used. For example, one or more of the gases exemplified above as the silicon hydride gas may be used as the source gas.

As the inert gas, for example, a nitrogen (N₂) gas or a rare gas such as argon (Ar) gas, helium (He) gas, neon (Ne) gas and xenon (Xe) gas may be used. The same also applies to each step described later.

<Reactive Gas Supply Step S5 and Purge Gas Supply Step S6>

After the purge gas supply step S4 is completed, the reactive gas excited by the plasma is supplied onto the wafers 200 in the process chamber 201 (step S5).

In the present step, the opening and the closing of the valves 243b, 243c and 243d can be controlled in the same manners as those of the valves 243a, 243c and 243d in the source gas supply step S3. After a flow rate of the reactive gas is adjusted by the MFC 241b, the reactive gas whose flow rate is adjusted is supplied into the process chamber 201 through the nozzle 249b and the gas supply holes 250b. When supplying the reactive gas, the high frequency power (RF power) (in the present embodiments, the frequency of the high frequency power is set to 27.12 MHz) is supplied (or applied) to the electrodes 300 from the high frequency power supply 320. The reactive gas supplied into the process chamber 201 is excited into the plasma state in the process chamber 201, is supplied onto the wafers 200 as the active species, and is exhausted through the exhaust pipe 231.

For example, process conditions of the present step are as follows:
A process temperature: from the room temperature (25° C.) to 550° C., preferably from 400° C. to 500° C.;
A process pressure: from 1 Pa to 300 Pa, preferably from 10 Pa to 100 Pa;
A supply flow rate of the reactive gas: from 0.1 slm to 10 slm;
A supply time (time duration) of supplying the reactive gas: from 1 second to 100 seconds, preferably from 1 second to 50 seconds;
A supply flow rate of the inert gas (for each gas supply pipe): from 0 slm to 10 slm;
The RF power: from 50 W to 1,000 W; and

The frequency of the RF power: 27.12 MHz.

By supplying the reactive gas (which is excited into the plasma state) onto the wafer 200 in accordance with the process conditions described above, the first layer formed on the surface of the wafer 200 is modified by the action between ions generated in the plasma and the active species which is electrically neutral. Thereby, the first layer is modified into a second layer.

For example, when an oxidizing gas (oxidizing agent) such as an oxygen-containing gas is used as the reactive gas, by exciting the oxygen-containing gas into the plasma state, an oxygen-containing active species is generated. Then, the oxygen-containing active species is supplied onto the wafer 200. In such a case, the first layer formed on the surface of the wafer 200 is oxidized by the action of the oxygen-containing active species as an oxidation process (modification process). In such a case, for example, when the first layer is the silicon-containing layer, the silicon-containing layer serving as the first layer is modified into a silicon oxide layer (also simply referred to as a “SiO layer”) serving as the second layer.

For example, when a nitriding gas (nitriding agent) such as a gas containing nitrogen (N) and hydrogen (H) is used as the reactive gas, by exciting the gas containing nitrogen and hydrogen into the plasma state, an active species containing nitrogen and hydrogen is generated. Then, the active species containing nitrogen and hydrogen is supplied onto the wafer 200. In such a case, the first layer formed on the surface of the wafer 200 is nitrided by the action of the active species containing nitrogen and hydrogen as a nitridation process (modification process). In such a case, for example, when the first layer is the silicon-containing layer, the silicon-containing layer serving as the first layer is modified into a silicon nitride layer (also simply referred to as a “SiN layer”) serving as the second layer.

After the first layer is modified into the second layer, the valve 243b is closed to stop a supply of the reactive gas into the process chamber 201. Further, a supply of the RF power to the electrodes 300 is also stopped. In the purge gas supply step S6, a residual gas remaining in the process chamber 201 such as the reactive gas and reaction by-products in the process chamber 201 is removed from the process chamber 201 according to substantially the same procedures and conditions as those of the purge gas supply step S4.

As described above, as the reactive gas, for example, the oxygen-containing gas or the gas containing nitrogen (N) and hydrogen (H) may be used. As the oxygen-containing gas, for example, a gas such as oxygen (O₂) gas, nitrous oxide (N₂₀) gas, nitrogen monoxide (NO) gas, nitrogen dioxide (NO₂) gas, ozone (O₃) gas, hydrogen peroxide (H₂O₂) gas, water vapor (H₂O), ammonium hydroxide (NH₄ (OH)) gas, carbon monoxide (CO) gas and carbon dioxide (CO₂) gas may be used. As the gas containing nitrogen and hydrogen, for example, a hydrogen nitride gas such as ammonia (NH₃) gas, diazene (N₂H₂) gas, hydrazine (N₂H₄) gas and N₃H₈ gas may be used. For example, one or more of the gases exemplified above as the oxygen-containing gas or the gas containing nitrogen and hydrogen may be used as the reactive gas.

For example, various gases exemplified in the step S4 may be used as the inert gas.

### <Performing Predetermined Number of Times: S7>

By performing the cycle wherein the steps S3, S4, S5 and S6 described above are performed non-simultaneously (that is, in a non-overlapping manner) in this order a predetermined number of times (n times, wherein n is an integer equal to or greater than 1) (that is, at least once), a film of a predetermined composition and a predetermined thickness is formed on the wafer 200. It is preferable that the cycle is repeatedly performed a plurality of times. That is, it is preferable that the cycle is repeatedly performed a plurality of times until a thickness of a stacked layer constituted by the first layer and the second layer reaches a desired thickness while a thickness of the first layer formed per each cycle is smaller than the desired thickness. For example, when forming the silicon-containing layer as the first layer and the SiO layer as the second layer, a silicon oxide film (also simply referred to as a “SiO film”) is formed as the film. Further, for example, when forming the silicon-containing layer as the first layer and the SiN layer as the second layer, a silicon nitride film (also simply referred to as a “SiN film”) is formed as the film.

### <Returning to Atmospheric Pressure Step: S8>

After the film-forming step described above is completed, the inert gas is supplied into the process chamber 201 through each of the gas supply pipes 232c and 232d, and then is exhausted through the exhaust pipe 231. The process chamber 201 is thereby purged with the inert gas such that the residual reactive gas or the reaction by-products remaining in the process chamber 201 are removed from the process chamber 201 (purging by the inert gas). Thereafter, the inner atmosphere of the process chamber 201 is replaced with the inert gas (substitution by the inert gas), and the inner pressure of the process chamber 201 is returned to the atmospheric pressure (returning to atmospheric pressure step S8).

### <Boat Unloading and Substrate Discharging Step: S9>

Then, the seal cap 219 is lowered by the boat elevator 115 and the lower end of the manifold 209 is opened. The boat 217 with the wafers 200 processed as described above and charged therein is transferred (or unloaded) out of the reaction tube 203 through the lower end of the manifold 209 (boat unloading step). After the boat 217 is unloaded, the shutter 219s is moved. Thereby, the lower end opening of the manifold 209 is sealed by the shutter 219s through the O-ring 220c (shutter closing step). The wafers 200 processed as described above are taken out of the reaction tube 203, and then discharged from the boat 217 (wafer discharging step). In addition, an empty boat 217 (that is, the boat 217 without accommodating the wafers 200) may be loaded into the process chamber 201 after the wafer discharging step is performed.

In the present embodiments, the inner pressure of the furnace (that is, the process furnace 202) when the substrate processing is performed may be preferably controlled within a range of 2 Pa or more and 300 Pa or less. When the inner pressure of the furnace is lower than 2 Pa, the mean free path of the gas molecules becomes longer than the Debye length of the plasma, and the plasma directly hitting the wall of the furnace becomes noticeable. As a result, it may be difficult to suppress the generation of the particles. In addition, when the inner pressure of the furnace is higher than 300 Pa, the efficiency of generating the plasma is saturated so that generation amount of the plasma does not change even when the reactive gas is supplied. Thereby, the reactive gas may be wasted. In addition, since the mean free path of the gas molecules is shortened, the transport efficiency of the active species of the plasma to the wafers 200 may deteriorate.

### (3) Effects According to Present Embodiments

According to the present embodiments, by adjusting the shape (length or area) of the electrode, it is possible to uniformize the distribution of the plasma in the wafer region (that is, the wafer placement region) in the vertical direction. Thereby, it is possible to perform the substrate processing more uniformly by using the plasma.

### Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

For example, the embodiments mentioned above are described by way of an example in which the reactant (that is, the reactive gas) is supplied after the source material (that is, the source gas) is supplied. However, the technique of the present disclosure is not limited thereto. The technique of the present disclosure may also be applied when a supply order of the source material and the reactant is changed. That is, the technique of the present disclosure may be applied when the source material is supplied after the reactant is supplied. By changing the supply order, it is possible to change the quality or the composition of the film formed by performing the substrate processing.

For example, the embodiments mentioned above are described by way of an example in which the silicon oxide film (SiO film) or the silicon nitride film (SiN film) is formed on the wafer 200. However, the technique of the present disclosure is not limited thereto. For example, the technique of the present disclosure may also be preferably applied to form, on the wafer 200, a silicon-based oxide film such as a silicon oxycarbide film (SiOC film), a silicon oxycarbonitride film (SiOCN film) and a silicon oxynitride film (SiON film).

For example, the technique of the present disclosure may also be applied to form, on the wafer 200, various films such as the SiN film, the SiON film, the SiOCN film, the SiOC film, a silicon carbonitride film (SiCN film), a silicon boronitride film (SiBN film), a silicon borocarbonitride film (SiBCN film) and a boron carbonitride film (BCN film). In such cases, instead of the gases described above or in addition to the gases described above, a nitrogen (N)-containing gas such as ammonia (NH₃) gas, a carbon (C)-containing gas such as propylene (C₃H₆) gas and a boron (B)-containing gas such as boron trichloride (BCl₃) gas may be used to form the various films. In addition, a sequential order of supplying the gases described above may be appropriately changed. When forming the various films, the process conditions of the film-forming process for forming the various films may be substantially the same as those of the film-forming process according to the embodiments mentioned above, and it is possible to obtain substantially the same effects as those of the embodiments mentioned above. In such cases, the oxidizing agent serving as the reactive gas may be the same as that of the embodiments mentioned above.

For example, the technique of the present disclosure may also be preferably applied to form, on the wafer 200, a metal-based oxide film (or a metal-based nitride film) containing a metal element such as titanium (Ti), zirconium (Zr), hafnium (Hf), tantalum (Ta), niobium (Nb), aluminum (Al), molybdenum (Mo) and tungsten (W).

That is, the technique of the present disclosure may also be preferably applied to form a metalloid film containing a metalloid element or a metal-based film containing a metal element. The process procedures and the process conditions of the film-forming process of the metalloid film or the metal-based film may be substantially the same as those of the film-forming process according to the embodiments or the modified examples described above. Even in such a case, it is possible to obtain substantially the same effects as those of the embodiments mentioned above.

It is preferable that recipes used in the film-forming process are prepared individually in accordance with process contents and stored in the memory 121c via an electric communication line or the external memory 123. When starting various processes, it is preferable that the CPU 121a selects an appropriate recipe among the recipes stored in the memory 121c in accordance with the process contents. Thus, various films of different composition ratios, qualities and thicknesses can be formed in a reproducible manner and in a universal manner by using a single substrate processing apparatus. In addition, since a burden on an operating personnel of the substrate processing apparatus can be reduced, various processes can be performed quickly while avoiding a malfunction of the substrate processing apparatus.

The recipe described above is not limited to creating a new recipe. For example, the recipe may be prepared by changing an existing recipe stored in the substrate processing apparatus in advance. When changing the existing recipe to a new recipe, the new recipe may be installed in the substrate processing apparatus via the electric communication line or the recording medium in which the new recipe is stored. In addition, the existing recipe already stored in the substrate processing apparatus may be directly changed to the new recipe by operating the input/output device 122 of the substrate processing apparatus.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

According to some embodiments of the present disclosure, it is possible to perform the substrate processing more uniformly.

What is claimed is:

1. A substrate processing apparatus comprising:
a process chamber in which a substrate is processed;
a plurality of primary electrodes connected to a high frequency power supply provided outside the process chamber, wherein each of the plurality of primary electrodes is configured to be folded back at an upper portion thereof; and
a secondary electrode to which a reference potential is applied.

2. The substrate processing apparatus of claim 1, wherein the secondary electrode is arranged between the plurality of primary electrodes.

3. The substrate processing apparatus of claim 1, further comprising
one or more secondary electrodes,
wherein the plurality of primary electrodes are arranged alternately with a plurality of secondary electrodes constituted by the secondary electrode and the one or more secondary electrodes.

4. The substrate processing apparatus of claim 3, wherein the number of the plurality of primary electrodes is equal to the number of the plurality of secondary electrodes.

5. The substrate processing apparatus of claim 1, wherein lengths of the plurality of primary electrodes are different from one another.

6. The substrate processing apparatus of claim 1, wherein areas of the plurality of primary electrodes are different from one another.

7. The substrate processing apparatus of claim 1, wherein a length of each of the plurality of primary electrodes is longer than a length of the secondary electrode.

8. The substrate processing apparatus of claim 1, wherein the plurality of primary electrodes and the secondary electrode are of a flat plate shape.

9. The substrate processing apparatus of claim 8, wherein each of the plurality of primary electrodes is provided with a folded structure.

10. The substrate processing apparatus of claim 1, further comprising
a heater configured to heat the substrate.

11. The substrate processing apparatus of claim 10, wherein the plurality of primary electrodes and the secondary electrode are provided in an inner side of the heater.

12. The substrate processing apparatus of claim 10, wherein the plurality of primary electrodes and the secondary electrode are provided between the process chamber and the heater.

13. The substrate processing apparatus of claim 1, further comprising
a substrate retainer configured accommodate and support the substrate and one or more substrates.

14. The substrate processing apparatus of claim 13, wherein each of the plurality of primary electrodes is configured to be folded back in a direction opposite to a stacking direction of the substrate and one or more substrates.

15. The substrate processing apparatus of claim 13, wherein the plurality of primary electrodes and the secondary electrode are arranged along a stacking direction of the substrate and one or more substrates.

16. The substrate processing apparatus of claim 1, wherein each of the plurality of primary electrodes is connected to the high frequency power supply at a lower portion thereof.

17. An electrode assembly comprising:
a plurality of primary electrodes connected to a high frequency power supply, wherein each of the plurality of primary electrodes is configured to be folded back at an upper portion thereof; and
a secondary electrode to which a reference potential is applied.

18. A substrate processing method comprising:
(a) loading a substrate into a process chamber of a substrate processing apparatus, wherein the substrate processing apparatus comprises:
the process chamber in which the substrate is processed;
a plurality of primary electrodes connected to a high frequency power supply provided outside the process chamber, wherein each of the plurality of primary electrodes is configured to be folded back at an upper portion thereof; and
a secondary electrode to which a reference potential is applied; and
(b) generating a plasma in the process chamber.

19. A method of manufacturing a semiconductor device, comprising:
the substrate processing method of claim 18.

20. A non-transitory computer-readable recording medium storing a program that causes a substrate processing apparatus, by a computer, to perform a process comprising the substrate processing method of claim 18.
